(19) United States
(12) Patent Application Publication
(10) Pub. No.: US 2001/0017355 A1
(43) Pub. Date: Aug. 30, 2001

(54) Electron beam lithography apparatus and lithography method

(76) Inventor: Kazui Mizuno, Mito-shi (JP)

Correspondence Address: Edward W. Greason, Kenyon & Kenyon, One Broadway, NY, 10004, US

(21) Appl. No.: 09/792,357

(22) Filed: Feb. 23, 2001

(30) Foreign Application Priority Data
Feb. 25, 2000 (JP) 2000-54457

(51) Int. Cl. H01J 37/302

(52) U.S. Cl. 250/492.22

(57) ABSTRACT

An electron beam lithography apparatus includes a control device in which, for each column stripe in each drawing time of multiple drawing, optional conditions of dividing a pattern to be drawn on the sample can be set; and a time obtained by dividing a total irradiation time by the number of total drawing times is set to an electron beam-irradiation time. Further, the control device controls a deflection device so as to deflect the electron beam in accordance with the set conditions of pattern-division and the set electron beam-irradiation time.

### BACKGROUND OF THE INVENTION

The present invention relates to an electron beam lithography apparatus and a lithograph method, in which a pattern is drawn (lithographed) on a sample for lithography while it is continuously moved.

First, a step and repeat method is known as a drawing method of drawing a pattern on a sample for lithography in conventional electron beam lithography apparatuses. In this drawing method, since the drawing on a sample for lithography is not performed during the motion of the sample, the time of the motion is no use, and this has been an obstacle to improving the throughput of an electron beam lithography apparatus by reducing the drawing time.

On the other hand, in a drawing method in which a sample for lithography is continuously moved (the sample is moved by driving a sample-hold means, called a stage, on which the sample is mounted), the drawing on the sample can be performed while the sample is continuously moved. Accordingly, the time of the motion, which has been no use, can be practically utilized, and the drawing time can be reduced.

Here, as the continuos sample-motion method, two methods of; a constant speed motion method in which a sample for lithography is moved at a constant speed; and a variable speed motion method in which the speed of sample motion is changed depending on denseness of a pattern to be drawn; have been devised. In the above continuous sample-motion methods, the width of an area on which a pattern is drawn while a sample is moved (generally, this width is called a stripe width, and is a lateral range in which the pattern is drawn by deflecting an electron beam in the direction perpendicular to that of the sample motion), is restricted to a maximum of about 5 mm by considering drawing accuracy, particularly, connection accuracy between neighboring stripes.

In order to improve drawing accuracy, it is effective in the light of obtaining an average effect, to implement multiple drawing. However, since the multiple drawing increases the time for drawing, this causes a new problem in that the throughput of an electron beam lithography apparatus is deteriorated. Particularly, since the pattern data-division conditions for a column stripe is set before the starting of drawing in a column stripe, if the same pattern data is multiply drawn by the multiple drawing, the number of total drawing shots (the number of total shots to draw all divided pattern data on a sample) is increased by the multiple times in the multiple drawing. Therefore, in the multiple drawing, there has been a problem in that the total drawing time cannot be reduced, and this makes it impossible to improve the throughput of an electron beam lithography apparatus.

### SUMMARY OF THE INVENTION

The present invention has been achieved to solve the above described problems, and is aimed at a providing an electron beam lithography apparatus and a lithography method which is capable of reducing the number of total drawing shots, thereby to improve the throughput of the electron beam lithography apparatus.

To achieve the above objective, optional conditions of dividing pattern data can be set in the present invention, whereby the number of total drawing shots can be reduced.

More specifically, the present invention provides an electron beam lithography apparatus comprising: a sample-holding device for holding a sample for lithography, which is driven to move the sample; a drive device for driving the sample-holding device; an electron beam-generation device for generating an electron beam to draw a pattern on the sample; a deflection device for deflecting the generated electron beam to a desired position on the sample; a length-measuring device for measuring the position of the sample; and a control device in which conditions of pattern data-division are set to divide a pattern to be drawn on the sample into sub-patterns of desired sizes, for controlling the deflection device in accordance with the set conditions of pattern data-division.

Further, the present invention provides an electron beam lithography method comprising the steps of: deflecting an electron beam to a desired position on an sample for lithography; controlling a deflection device so as to irradiate a designated position on the sample with the electron beam; and setting optional conditions of dividing pattern data to be drawn on the sample into sub pattern-data of desired sizes, in multiple drawing; wherein the electron beam is controlled to be deflected in accordance with the set conditions of dividing patter data.

### BRIEF DESCRIPTION OF THE DRAWINGS

FIG. 1 is a schematic diagram showing the whole composition of an electron beam lithography apparatus of an embodiment according to the present invention.

FIG. 2 is an illustration conceptually showing a drawing method of drawing a pattern on deflection regions in a column stripe on a sample for lithography.

FIG. 3 is a flow chart of control processes performed in a multiple drawing method of an embodiment according to the present invention.

FIGS. 4(a), 4(b), and 4(c) are illustrations showing an example of deflection regions provided in pattern data-division for double drawing of the present invention.

FIGS. 5(a), 5(b), 5(c), and 5(d) are illustrations showing an example of deflection regions provided in pattern data-division for triple drawing of the present invention.

### DETAILED DESCRIPTION OF THE EMBODIMENTS

Hereafter, details of the embodiments will be explained with reference to the drawings.

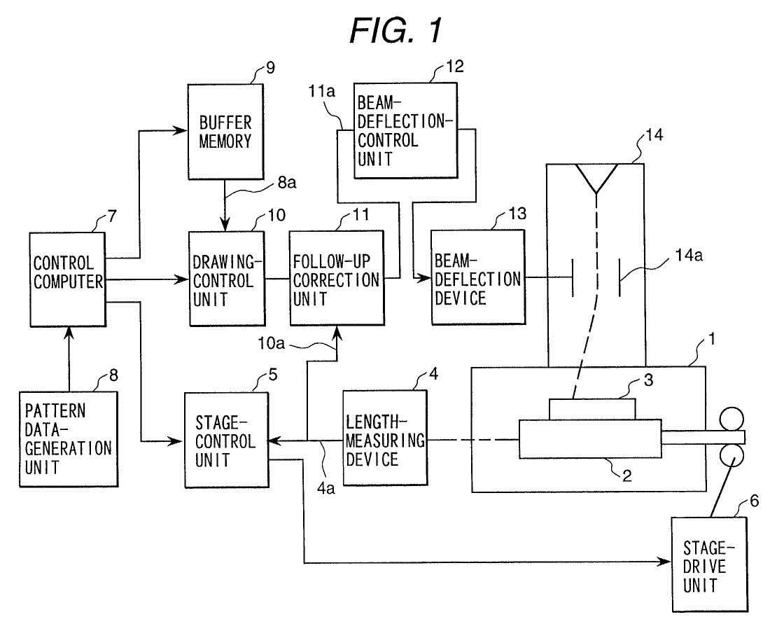

FIG. 1 shows the whole composition of an electron beam lithography apparatus of an embodiment according to the present invention.

In FIG. 1, a sample-hold means 2 (hereafter referred to as a stage 2) for holding a sample 3 for lithograph on it is situated in a main potion 1 of an electron beam lithography apparatus. Further, the position of the sample 3, that is, the position of the stage 2, is measured by a length-measuring device 4.

The stage 2 is connected to a stage-drive unit 6 so as to move the sample 3. Thus, the sample 3 is moved by moving the stage 2. The stage-drive unit 6 includes a drive mechanism such as an electrically-driven (motor-driven) device, a hydraulic device, a pneumatic device, etc. Further, a stage-control signal is sent to the stage-drive unit 6 from a stage-control unit 5, and the position of the stage 2 is controlled, that is, moved by the stage-control signal generated based on an instruction signal sent from a control computer 7.

Further, drawing pattern data are sent to the control computer 7 from a pattern data-generation unit 8, and the pattern data are rearranged in a unit of one column stripe in accordance with the order of column stripes to be drawn on the sample 3, which is instructed by the control computer 7. The rearranged pattern data 8a are transferred to a buffer memory 9 from the control computer 7, and they are stored in the buffer memory 9.

Furthermore, a drawing-control unit 10 is controlled by the control computer 7, and the drawing-control unit 10 starts drawing operations in response to a drawing-start instruction sent from the control computer 7. When the drawing-control unit 10 receives the drawing-start instruction from the control computer 7, the unit 10 reads out a set of pattern data 8a in turn from the buffer memory 9, according to the predetermined order. Moreover, the unit 10 creates shot data 10a by decomposing the read-out pattern data into respective shot data, and calculating the position of each shot, and sends the shot data 10a to a follow-up correction unit 11.

The follow-up correction unit 11 calculates deflection data based on the position data 4a of the stage 2, which are measured by the length-measuring device 4, and the shot data 10a. Further, if the stage 2 enters the deflectable range, the unit 11 starts an electron optical mirror system composed of a beam-deflection-control unit 12 and a beam-deflection device 13, which deflect an electron beam to a desired position on the sample.

The beam-deflection-control unit 12 deflects an electron beam 14a ejected from an electron beam generation means 14 (hereafter referred to as an electron gun 14) to draw a pattern on the sample 3, which is held on the stage 2 by using the beam-deflection device 13, in accordance with deflection data 11a.

If the sample continuous-motion type drawing is performed, for each column stripe, the control computer 7 starts the drawing-control unit 10 to draw the pattern, and starts the stage-motion control unit 5 so as to move the stage 2.

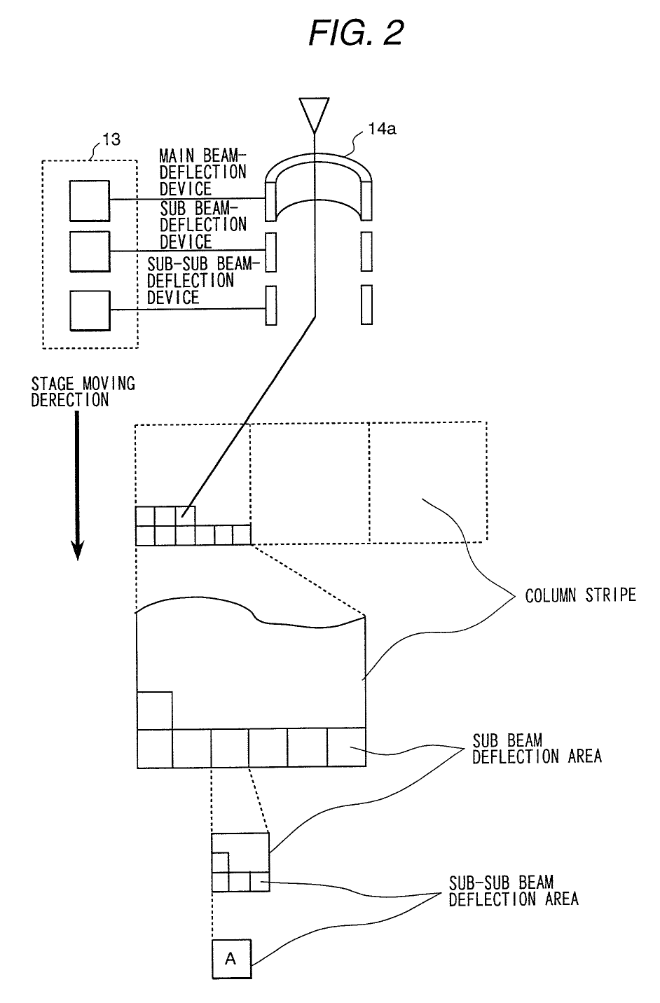

The fundamental composition and operation of the electron beam lithography apparatus is described in the above. A drawing method of drawing a pattern on the region inside a column stripe, is explained bellow with reference to FIG. 2.

In this drawing method of drawing a pattern on the region inside a column stripe, the region inside a column stripe is divided into sub deflection regions and sub-sub deflection regions as shown in FIG. 2, in two stages. That is, assuming that the direction of motion of the stage 2 is Y direction, and the direction perpendicular to the Y direction is X direction, a drawn region is renewed in the Y direction synchronizing with the motion of the stage 2 while a drawn region is sequentially renewed in X direction.

Here, the beam-deflection device 13 is composed of a main deflection device 13a, a sub deflection device 13b, and a sub-sub deflection device 13c, and these deflection devices are arranged in order of the main deflection device 13a, the sub deflection device 13b, and the sub-sub deflection device 13c, viewed from the electron gun 14. Further, the control of electron beam-deflection is performed by a selected combination of these deflection devices. Meanwhile, the control of beam-deflection for a sub deflection region in the deflection region and a sub-sub deflection region in the sub deflection region are controlled by the sub deflection device 13b and the sub-sub deflection device 13c, respectively.

Also, the positioning of drawn data in the sub-sub deflection region is controlled by the sub-sub deflection device 13c.

Further, it is needless to say that each of the main deflection device 13a, the sub deflection device 13b, and the sub-sub deflection device 13c, is controlled by the beam-deflection-control unit 12.

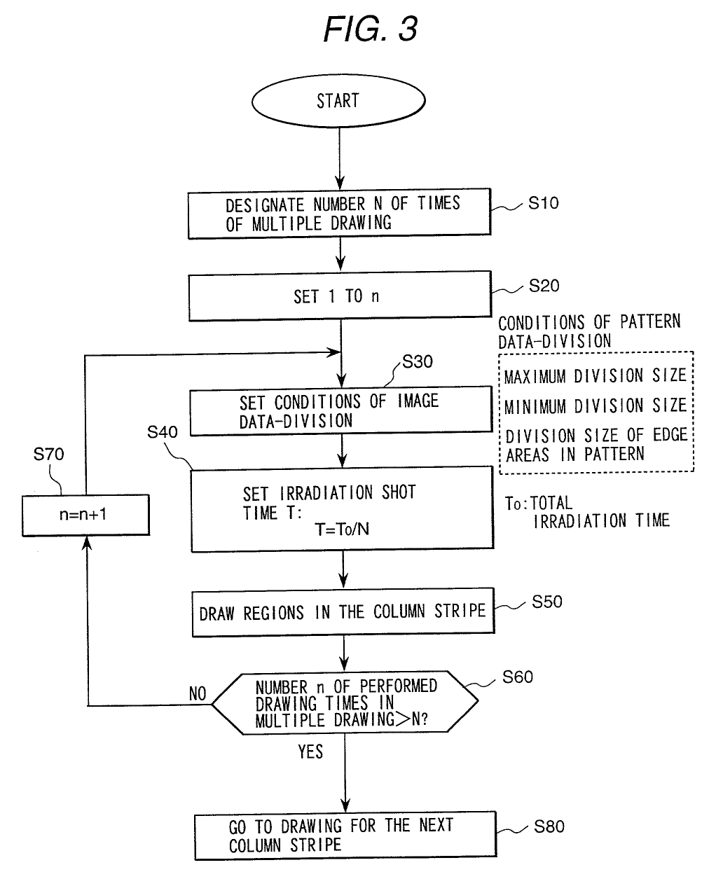

A flow chart of control processes performed by a multiple drawing method of an embodiment according to the present invention FIG. 3 is explained bellow, and this control process flow is executed by the control computer 7.

In FIG. 3, the number N of times of the multiple drawing is designated in step S10, and 1 is first set to the present number n of times of the multiple drawing in step S20. Here, (n=1) means that the drawing is first performed after the start of the control processes for the multiple drawing.

Next, in step S30, the conditions of drawn data (pattern data)-division is set in the first step of the control processes of drawing for each column stripe. Details of setting the conditions of drawn data (pattern data)-division, which is set in step S30, will be explained later.

In the setting of the conditions of drawn data-division, respective parameter values can be optionally set by setting the following conditions, that is: the conditions of pattern data-division such as the maximum division size, the minimum division size, the division size for edge areas, the conditions of dividing a pattern denseness map for proximity effect-correction, etc.; the conditions of smoothing a pattern denseness map for the proximity effect-correction; the positioning time of pattern data for each drawing; and so forth. In this way, delicate drawing-conditions can be set in each drawing time of the multiple drawing for each column stripe.

After setting the conditions of pattern data-division in step 30, the irradiation shot time T is set in step S40. This irradiation shot time T is set in inverse proportion to the number N of times of the drawing-repetition (the multiple drawing). Specifically, a time obtained by dividing the total irradiation time T₀ by the number N of times of the multiple drawing, is set to the irradiation shot time T.

Meanwhile, although the irradiation shot time T is set in inverse proportion to the number N of times of the multiple drawing, the method of determining the irradiation shot time T is not restricted to the above method, and various methods of determining the irradiation shot time t are possible.

Next, the sample 3 is irradiated with the electron beam 14a by the electron gun 14 in step S50, and the drawing is performed according to the conditions of pattern data-division, which has been set in step S30.

After the above drawing, it is determined in step 60 whether or not the present times n of the multiple drawing reaches the designated number N. If the number n does not reach the number N, the number n of drawing times is incremented by 1, and the processing returns to step 30. Further, the above process is repeated.

On the other hand, if the number n does not reach the number N, the processing goes to step S80, and the drawing for the next column stripe is performed.

In the drawing of the next column stripe also, the same processes as those of steps S10-S80 shown in FIG. 3 are performed, and the corresponding pattern data are drawn on the sample for lithography.

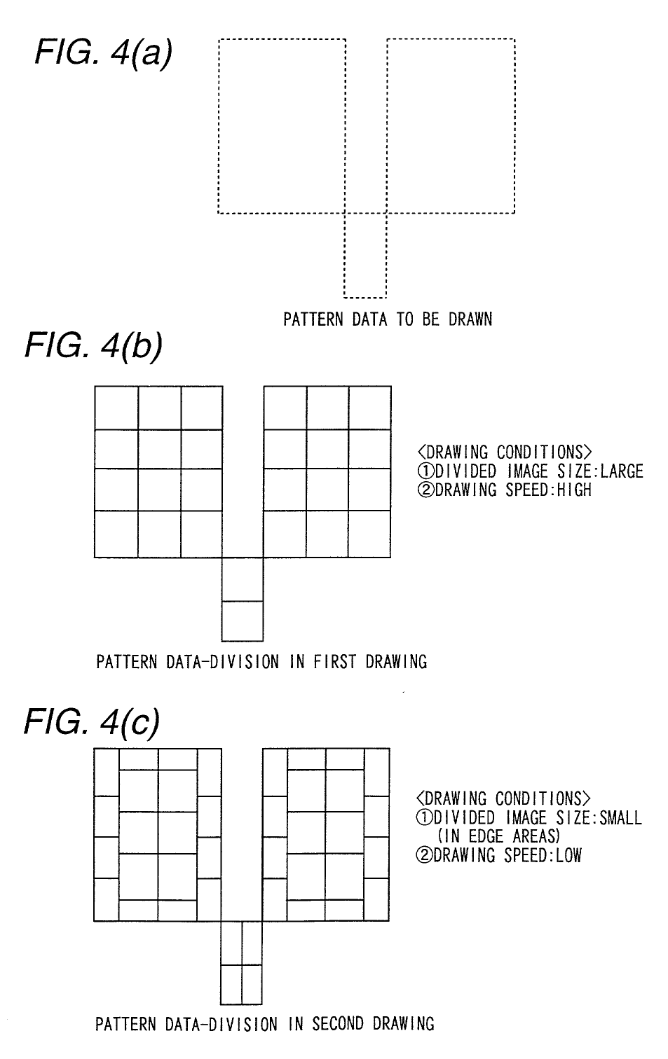

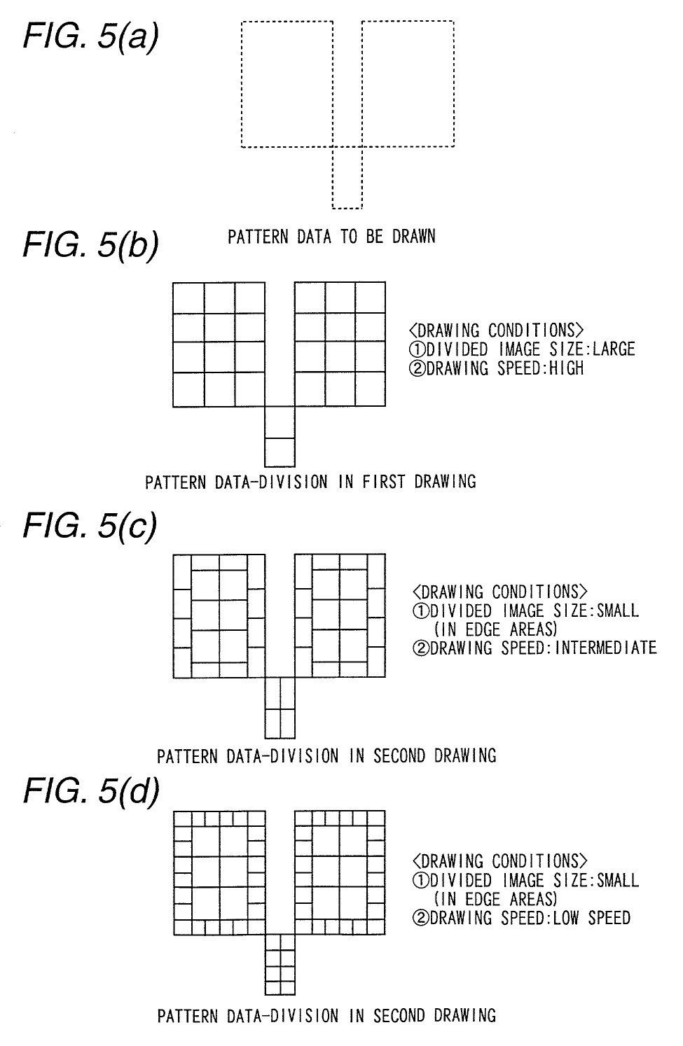

Next, the setting of the conditions of pattern data-division, which is performed in step S30, is explained bellow with reference to FIGS. 4(a), 4(b), and 4(c), and FIGS. 5(a), 5(b), 5(c), and 5(d).

Meanwhile, FIGS. 4(a), 4(b), and 4(c) show an example of deflection regions provided in the pattern data-division for the double drawing of the present invention, and FIGS. 5(a), 5(b), 5(c), and 5(d) show an example of deflection regions provided in the pattern data-division for the triple drawing of the present invention.

As shown in FIGS. 4(a), 4(b), and 4(c), in the first-time drawing, the maximum shot size is set as the size such as that shown in FIG. 4(b) so that the size of pattern data-division for the pattern data shown in FIG. 4(a) is as large as possible. If the pattern data is divided under the condition of the set maximum division size, the number of the shots obtained by this division of the pattern data can be minimized. Thus, it is possible to move the stage 2 at a high speed, which in turn can reduce the drawing time for each column stripe.

Next, in the second-time drawing, the division size of edge areas in the pattern data is set small as shown in FIG. 4(c). By this division, it is possible to suppress what is called beam blurring which causes a trouble if the shot size is small, and the suppressing of beam blurring can improve the size accuracy of a pattern drawn on the sample 3 for lithography.

Conventionally, since it has been necessary to set a small division size for edge areas in both the first and second drawings, the drawing time has required a long time. On the other hand, by this embodiment, since the pattern data is divided by the maximum shot size in the first drawing, the total drawing time can be reduced.

Further, a case wherein the triple drawing is performed is explained bellow with reference to FIGS. 5(a), 5(b), 5(c), and 5(d). In this case, the conditions of edge areas-division are changed between the second drawing and the third drawing in order to improve the size accuracy of the drawn pattern on the sample 3.

As shown in FIGS. 5(a), 5(b), 5(c), and 5(d), in the first-time drawing, the maximum shot size is set as the size such as that shown in FIG. 5(b) so that the size of pattern data-division for the pattern data shown in FIG. 5(a) is as large as possible. Next, in the second-time drawing, the division size of edge areas in the pattern data is set small as shown in FIG. 5(c).

Moreover, in the third-time drawing, the division size of edge areas in the pattern data is set smaller as shown in FIG. 5(d) than that shown in FIG. 5(c). In this case, since the connection portions in shots are changed in the respective drawing times of the multiple drawing, the accuracy of the shot connections can be improved. Under the above conditions of pattern data-division, the drawing speed in the first drawing, the second drawing, and the third drawing is high, intermediate, and low, respectively.

According to the above embodiments of the present invention, in the sample continuous-motion drawing method, since the number of total drawing shots can be reduced by setting the conditions of pattern data-division for each column stripe in the multiple drawing, the throughput of the electron beam lithography apparatus can be improved due to the reduction of the total drawing time. Further, by controlling the shot irradiation time to be inversely proportional to the number of total shots also, the throughput of the electron beam lithography apparatus can be improved due to the reduction of the total drawing time also. Furthermore, by changing the conditions of pattern data-division for each column stripe, since the connection portions of shots are changed in each drawing time, the accuracy of the shot connections can be improved.

As described above, in accordance with the present invention, by setting optional conditions of pattern data-division for each column stripe in the multiple drawing, the number of the total drawing shots can be reduced, and the throughput of the electron beam lithography apparatus can be improved due to the reduction of the total drawing time.

What is-claimed is:

1. An electron beam lithography apparatus comprising:
a sample-holding device for holding a sample for lithography, which is driven to move said sample;
a drive device for driving said sample-holding device;
an electron beam-generation device for generating an electron beam to draw a pattern on said sample;
a deflection device for deflecting said generated electron beam to a desired position on said sample;
a length-measuring device for measuring the position of said sample; and
a control device in which conditions of pattern data-division are set to divide a pattern to be drawn on said sample into sub-patterns of desired sizes, for controlling said deflection device so as to deflect said electron beam in accordance with said set conditions of pattern data-division.

2. An electron beam lithography apparatus according to claim 1, wherein said deflection device includes a plurality of deflectors for deflecting an electron beam in the direction perpendicular to moving direction of said sample, and said control device controls a combination of deflectors selected from among said deflectors so as to deflect said electron beam in accordance with said conditions of pattern data-division.

3. An electron beam lithography apparatus according to claim 2, wherein said plurality of deflectors are a main deflector, a sub deflector, and a sub-sub deflector, and are arranged in order of said main deflector, said sub deflector, and said sub-sub deflector, viewed from said electron beam-generation device.

4. An electron beam lithography apparatus comprising:
a sample-holding device for holding a sample for lithography, which is driven to move said sample;
a drive device for driving said sample-holding device;
an electron beam-generation device for generating an electron beam to draw a pattern on said sample;
a deflection device for deflecting said generated electron beam to a desired position on said sample;
a length-measuring device for measuring the position of said sample; and
a control device including a control computer which controls said deflection device so as to irradiate a predetermined position on said sample with said electron beam;
wherein said control computer executes:
(1) a function for setting the number N of times of multiple drawing,
(2) a function for setting optional conditions of dividing pattern data to be drawn, for each column stripe,
(3) a function for setting an irradiation time of said electron beam,
(4) a function for outputting an instruction signal to start operations of drawing pattern data on said sample, and
(5) a function for determining whether or not the number n of times of the performed drawing reaches the set number N, and continuing said operations of said multiple drawing until said number n reaches the number N.

5. An electron beam lithography method comprising the steps of:
deflecting an electron beam to a desired position on an sample for lithography;
controlling a deflection device so as to irradiate a designated position on said sample with said electron beam; and
setting optional conditions of dividing pattern data to be drawn on said sample, into sub pattern-data of desired sizes, for each column stripe in multiple drawing;
wherein said electron beam is controlled to be deflected in accordance with said set conditions of dividing patter data.

6. An electron beam lithography method according to claim 5, further including the step of setting an optional electron beam-irradiation time for each drawing time in said multiple drawing, and irradiating said sample with said electron beam.

7. An electron beam lithography method according to claim 6, wherein a time obtained by dividing a total irradiation time by the number of total drawing times is set to said electron beam-irradiation time.

8. An electron beam lithography method according to claim 5, wherein an optional time is set to a time for positioning of pattern data to be drawn on said sample, in each drawn time in said multiple drawing.

9. An electron beam lithography method according to claim 5, further including the step of setting optional conditions of dividing pattern data to be drawn into sub-pattern data, used when creating a pattern denseness map for proximity effect-correction in each drawing time in said multiple drawing.

10. An electron beam lithography method according to claim 5, further including the step of setting optional conditions of smoothing, used when creating a pattern denseness map for proximity effect-correction in each drawing time in said multiple drawing.

11. An electron beam lithography method comprising the steps of:
deflecting an electron beam to a desired position on an sample for lithography;
controlling a deflection device so as to irradiate a designated position on said sample with said electron beam; and
setting optional conditions of dividing pattern data to be drawn on said sample, into sub pattern-data of desired sizes, for each column stripe in multiple drawing;
wherein an control computer for performing the step of controlling said deflection device executes the steps of:
(1) setting the number N of times of multiple drawing,
(2) setting conditions of dividing pattern data to be drawn,
(3) setting an irradiation time of said electron beam,
(4) outputting an instruction signal to start operations of drawing pattern data on said sample, and
(5) determining whether or not the number n of times of the performed drawing reaches the set number N, and continuing said operations of said multiple drawing until said number n reaches the number N.
